(19) United States
(12) Patent Application Publication
(10) Pub. No.: US 2010/0213592 A1
(43) Pub. Date: Aug. 26, 2010

(54) Semiconductor Module, Terminal Strip, Method for Manufacturing Terminal Strip, and Method for Manufacturing Semiconductor Module

(75) Inventors: Masatoshi Ishii, Shiga-Ken (JP); Yoshiyuki Yamaji, Shiga-Ken (JP)

Correspondence Address: IBM MICROELECTRONICS;INTELLECTUAL PROPERTY LAW, 1000 RIVER STREET, 972 E, ESSEX JUNCTION, VT, 05452, US

(73) Assignee: International Business Machines Corporation, Armonk, NY (US)

(21) Appl. No.: 12/707,776

(22) Filed: Feb. 18, 2010

(30) Foreign Application Priority Data
Feb. 24, 2009 (JP) 2009-40462

(51) Int. Cl. H01L 23/52; H01L 23/48; H01L 21/768; H01L 21/77

(52) U.S. Cl. 257/686; 257/774; 438/667; 438/109; 257/690; 257/E21.575; 257/E21.598; 257/E23.141; 257/E23.011

(57) ABSTRACT

To provide a semiconductor module, a terminal strip, a method for manufacturing the terminal strip, and a method for manufacturing the semiconductor module in which loop inductance is decreased.

A terminal strip includes a grounding (GND) conductor, power supply (VDD) conductors, signal line conductors, and insulators. The insulators intervene between the GND conductor and the VDD conductors. Similarly, the insulators intervene between the GND conductor and the signal line conductors. In the terminal strip, since the GND conductor and the VDD conductors are disposed close to each other, mutual inductance between GND wiring and VDD wiring can be increased. Thus, loop inductance can be decreased.

### BACKGROUND

The present invention relates to a semiconductor module, a terminal strip, a method for manufacturing the terminal strip, and a method for manufacturing the semiconductor module.

Package on Package (PoP) techniques for stacking (or laminating) a plurality of semiconductor packages including semiconductor chips so as to densely mount semiconductor chips have been developed. A plurality of functions of a Central Processing Unit (CPU), a memory, and the like can be implemented in a single PoP, using the techniques. Hereinafter, a PoP is called a semiconductor module.

Patent Document 1 describes a technique related to a three dimensional memory module in which a plurality of semiconductor device units are stack-connected to each other, using a bump connecting technique, each of the semiconductor device units including a carrier in which a circuit pattern is formed and a semiconductor chip flip-chip assembled to the carrier, and the carrier of the semiconductor device unit includes a chip selecting semiconductor device.

Japanese Unexamined Patent Application Publication No. 10-284683

### BRIEF SUMMARY

From the viewpoint of power supply quality (Power Integrity), it is important to reduce power supply voltage variations in a semiconductor module. It is effective in improving power integrity to decrease the resistance of a path in a semiconductor module, the path extending from a terminal (a VDD terminal) of a semiconductor chip connecting to a power supply (VDD) to a terminal (a GND terminal) of the semiconductor chip connecting to a ground (GND), as viewed from the semiconductor chip, and to increase VDD-GND capacitance. Additionally, it is important to decrease loop inductance L of a path in a semiconductor module, the path extending from the VDD terminal of a semiconductor chip to the GND terminal. This is because a potential drop proportional to the loop inductance L occurs due to variations over time in current passing through the path extending from the VDD terminal to the GND terminal.

Self-inductance and mutual inductance affect the loop inductance L. Here, it is assumed that, on a path in a semiconductor module, the path extending from the VDD terminal of a semiconductor chip to the GND terminal, a path to the VDD terminal (a path to the VDD terminal) and a path to the GND terminal (a path to the GND terminal) are disposed adjacent to each other. In this case, the loop inductance L is expressed as L=L1+L2−2×L12, using self-inductance L1 of the path to the VDD terminal, self-inductance L2 of the path to the GND terminal, and mutual inductance L12 between the path to the VDD terminal and the path to the GND terminal. Thus, when the mutual inductance L12 is increased, the loop inductance L can be decreased.

The mutual inductance is increased by shortening the physical distance between the path to the VDD terminal and the path to the GND terminal disposed adjacent to each other, i.e., bringing the path to the VDD terminal and the path to the GND terminal disposed adjacent to each other closer to each other.

It is an object of the present invention to provide a semiconductor module, a terminal strip, a method for manufacturing the terminal strip, and a method for manufacturing the semiconductor module in which loop inductance is decreased by increasing mutual inductance between a path to a VDD terminal and a path to a GND terminal disposed adjacent to each other.

A semiconductor module to which the present invention is applied includes a plurality of semiconductor packages each of which includes a semiconductor chip, and terminal strips that intervene between the plurality of semiconductor packages and connect the semiconductor packages to each other. Each of the terminal strips includes a first conductor that has a tabular shape and includes a plurality of through holes that extend in a strip thickness direction, a plurality of second conductors provided inside the plurality of through holes so that the second conductors extend from a top surface of the first conductor to reach a bottom surface of the first conductor, and insulators provided so that the insulators surround respective perimeters of the second conductors, the insulators intervening between the first conductor and the second conductors so as to electrically insulate the first conductor from the second conductors.

The first conductor may be connected to first potential, some of the plurality of second conductors may be connected to second potential different from the first potential, and all or some of the other second conductors may be used as signal lines. Moreover, the first potential may be ground potential.

Moreover, the second conductors used as the signal lines may have a smaller cross section than the second conductors connected to the second potential. Moreover, ones of the insulators provided so as to surround respective perimeters of the second conductors used as the signal lines may have a larger thickness than ones of the insulators provided so as to surround respective perimeters of the second conductors connected to the second potential, the insulators intervening between the first conductor and the second conductors.

Moreover, ones of the insulators provided so as to surround respective perimeters of the second conductors used as the signal lines may have a smaller dielectric constant than ones of the insulators provided so as to surround respective perimeters of the second conductors connected to the second potential.

A terminal strip that connects a plurality of semiconductor packages to each other includes a first conductor that has a tabular shape and includes a plurality of through holes that extend in a strip thickness direction, a plurality of second conductors provided inside the plurality of through holes so that the second conductors extend from a top surface of the first conductor to reach a bottom surface of the first conductor, and insulators provided so that the insulators surround respective perimeters of the second conductors, the insulators intervening between the first conductor and the second conductors so as to electrically insulate the first conductor from the second conductors. The present invention is applied to the terminal strip.

Moreover, the terminal strip may further include an insulating layer at each of the top surface and bottom surface of the first conductor.

As viewed from another aspect, a method for manufacturing a terminal strip that connects a plurality of semiconductor packages to each other comprises the steps of: forming a plurality of first through holes in a first conductor that has a tabular shape, filling the plurality of first through holes with an insulator, forming second through holes in the insulator in the first through holes, and filling the second through holes with a second conductor. The present invention is applied to the method.

Moreover, a method for manufacturing a semiconductor module comprises the steps of: manufacturing a terminal strip that connects a plurality of semiconductor packages to each other, and connecting the semiconductor packages via the terminal strip sandwiched by the semiconductor packages. The present invention is applied to the method. The steps of manufacturing the terminal strip include forming a plurality of first through holes in a first conductor that has a tabular shape, filling the plurality of first through holes with an insulator, forming second through holes in the insulator in the first through holes, and filling the second through holes with a second conductor.

According to the present invention, an affect of providing a semiconductor module, a terminal strip, a method for manufacturing the terminal strip, and a method for manufacturing the semiconductor module in which loop inductance is decreased can be achieved.

### BRIEF DESCRIPTION OF SEVERAL VIEWS OF THE DRAWINGS

FIG. 1 is a diagram describing a semiconductor module according to a first embodiment.

FIG. 2 is a cross sectional view describing the semiconductor module according to the first embodiment.

FIG. 3 is a cross sectional view describing the semiconductor module according to the first embodiment.

FIG. 4 is a plan view and a cross sectional view describing a terminal strip.

FIG. 5 is a diagram describing a method for manufacturing the terminal strip.

FIG. 6 is a diagram describing a method for manufacturing the semiconductor module.

FIG. 7 is a diagram showing respective semiconductor modules of an example and a comparative example.

FIG. 8 is a diagram showing the loop inductance capacitance of each of the respective semiconductor modules of the example and the comparative example.

FIG. 9 is a diagram showing a semiconductor module in which three semiconductor packages are stacked.

FIG. 10 is a diagram describing a semiconductor module according to a second embodiment.

FIG. 11 is a diagram showing the capacitance of the semiconductor module according to the second embodiment.

FIG. 12 is a plan view of a terminal strip for describing the terminal strip in a semiconductor module according to a third embodiment.

FIG. 13 is a plan view of a terminal strip for describing the terminal strip in a semiconductor module according to a fourth embodiment.

### REFERENCE NUMERALS

10: semiconductor module
20: semiconductor chip
30: semiconductor package
40: terminal strip
41: grounding (GND) conductor
42: power supply (VDD) conductor
43: signal line conductor
45: insulator

### DETAILED DESCRIPTION

Embodiments of the present invention will now be described in detail with reference to the attached drawings. The same reference numerals are assigned to the same components, and the description is omitted. Moreover, since the attached drawings just schematically illustrate the embodiments, the attached drawings are not based on a correct scale.

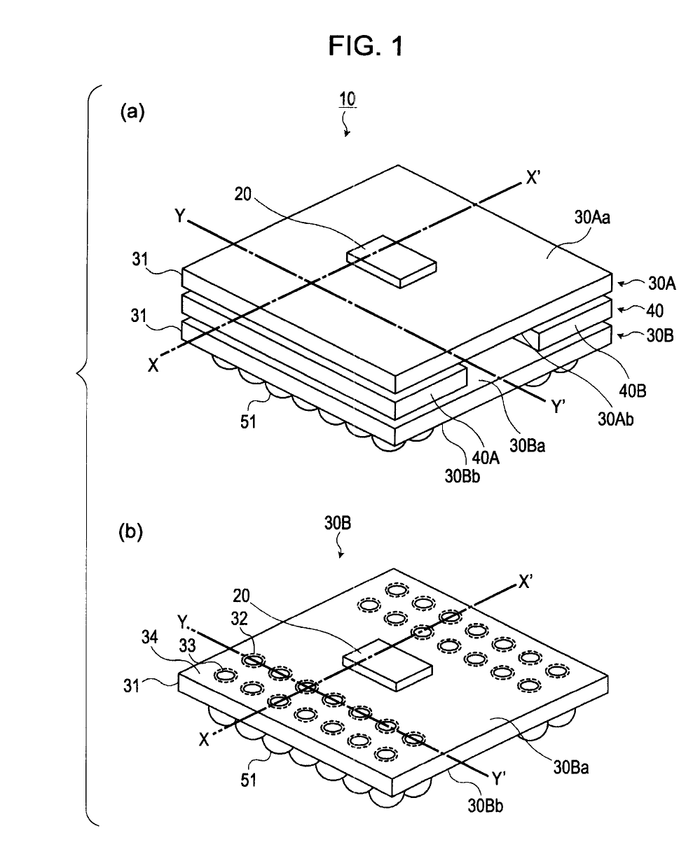

FIG. 1 is a diagram describing a semiconductor module 10 according to a first embodiment. FIG. 1(a) is a diagram showing the semiconductor module 10. On the other hand, FIG. 1(b) is a diagram showing a semiconductor package 30B constituting the semiconductor module 10.

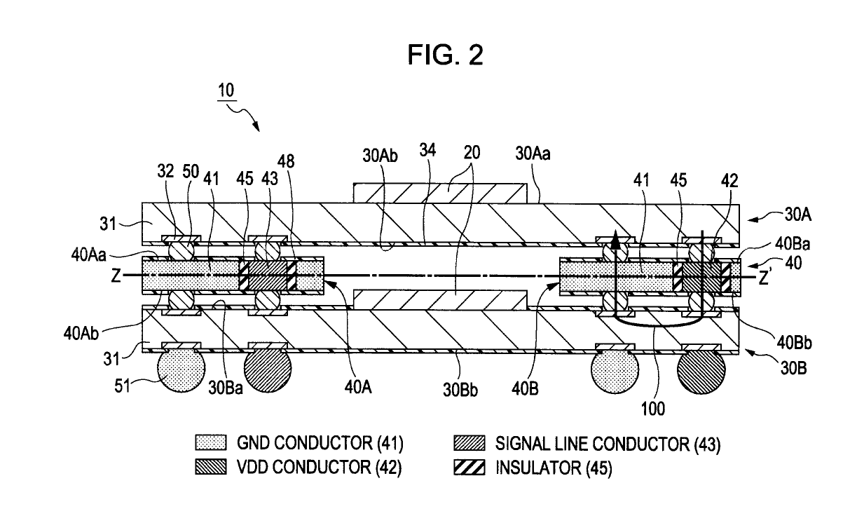

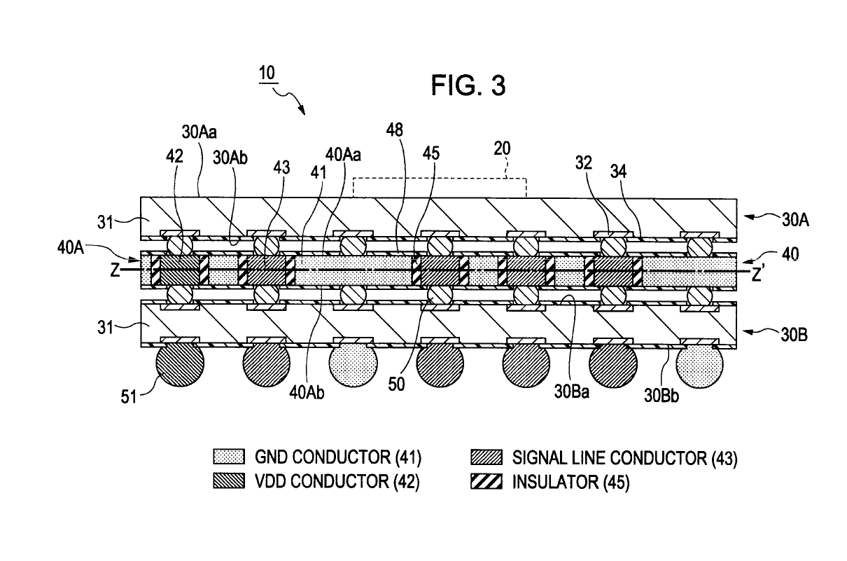

The semiconductor module 10 includes, for example, two semiconductor packages 30A and 30B and terminal strips 40A and 40B sandwiched between the semiconductor packages 30A and 30B (refer to FIGS. 2 and 3 described below), as shown in FIG. 1(a). In this case, the semiconductor packages 30A and 30B are called a semiconductor package 30 when being described in common. Moreover, the terminal strips 40A and 40B are called a terminal strip 40 when being described in common.

Each of the semiconductor packages 30A and 30B includes a semiconductor chip 20 and a printed wiring board 31. The semiconductor chip 20 is connected to the printed wiring board 31.

The semiconductor chip 20 may be a CPU or a memory composed of, for example, Si substrate. Moreover, the semiconductor chip 20 may be an Application-Specific Integrated Circuit (ASIC).

The semiconductor package 30 will next be described, taking the semiconductor package 30B shown in FIG. 1(b) as an example. The semiconductor package 30B is one of the two semiconductor packages 30A and 30B constituting the semiconductor module 10 and is disposed on the bottom side of the semiconductor module 10.

The printed wiring board 31 constituting the semiconductor package 30B is formed by laminating a plurality of glass epoxy substrates in which wiring of, for example, Cu foil is formed. A top surface 30Ba of the printed wiring board 31 constituting the semiconductor package 30B includes pads 32 each of which is covered by, for example, a solder layer 33 and includes an insulating layer 34 formed of, for example, a solder resist.

A solder resist is an insulative synthetic resin film covering the printed wiring board 31 to prevent solder from adhering to portions other than the pads 32. Moreover, the pads 32 are portions of wiring connecting the printed wiring board 31 to the terminal strip 40A or 40B, the semiconductor chip 20, another printed wiring board 31, and discrete components such as resistors and capacitors and are formed, the area of each of the pads 32 being enlarged.

Although not shown, at a bottom surface 30Ab of the printed wiring board 31 constituting the semiconductor package 30A, the pads 32, each of which is covered by the solder layer 33, and the insulating layer 34 formed of a solder resist are provided. The pads 32 are provided at portions connecting to the terminal strip 40A or 40B, as described above. On the other hand, the pads 32 except one of the pads 32 connecting to the semiconductor chip 20 are not provided at a top surface 30Aa of the semiconductor package 30A. This is because the top surface 30Aa of the semiconductor package 30A is not connected to the terminal strip 40.

Although the detailed description is omitted, the pads 32 provided in the printed wiring board 31 and terminals (for example, signal input and output terminals, a power supply terminal, and a grounding terminal) provided in the semiconductor chip 20 are connected to the printed wiring board 31 and the semiconductor chip 20 constituting the semiconductor package 30B by, for example, the flip-chip assembly method. In this case, instead of the flip chip assembly method, the wire bonding assembly method may be used.

On the other hand, a plurality of connection terminals 51 formed of, for example, solder balls for connecting to a mother board (not shown) are provided at the pads 32 at a bottom surface 30Bb of the printed wiring board 31 constituting the semiconductor package 30B.

The semiconductor module 10 according to the first embodiment constitutes a PoP in which the two semiconductor packages 30A and 30B are stacked (or laminated), sandwiching the terminal strip 40, as described above. The semiconductor module 10 performs signal processing, data processing, and the like on the basis of electrical power and signals supplied from the mother board including the semiconductor module 10.

FIG. 2 is a cross sectional view describing the semiconductor module 10 according to the first embodiment, taken along line X-X′ in FIG. 1. Moreover, FIG. 3 is a cross sectional view describing the semiconductor module 10 according to the first embodiment, taken along line Y-Y′ in FIG. 1.

The semiconductor packages 30A and 30B will now be described in more detail with reference to FIGS. 2 and 3. The plurality of pads 32 are provided at each of the bottom surface 30Ab of the printed wiring board 31 constituting the semiconductor package 30A and the top surface 30Ba and bottom surface 30Bb of the printed wiring board 31 constituting the semiconductor package 30B. The solder layer 33 (not shown) is provided at each of the pads 32 at each of the bottom surface 30Ab of the printed wiring board 31 constituting the semiconductor package 30A and the top surface 30Ba of the printed wiring board 31 constituting the semiconductor package 30B. The solder layer 33 and a solder layer 47 (not shown) provided in each of the terminal strips 40A and 40B are fused (or melt) together to constitute a connection portion 50. Moreover, the perimeter of each of the pads 32 is covered by the insulating layer 34.

At the bottom surface 30Ab of the printed wiring board 31 constituting the semiconductor package 30A, the terminal strips 40A and 40B are connected to the pads 32 on each of which the solder layer 33 is provided.

On the other hand, at the top surface 30Ba of the printed wiring board 31 constituting the semiconductor package 30B, the terminal strips 40A and 40B are connected to the pads 32 on each of which the solder layer 33 is provided. The connection terminals 51 connecting the semiconductor package 30B to the mother board (not shown) are provided at the pads 32 at the bottom surface 30Bb of the printed wiring board 31 constituting the semiconductor package 30B, as described above.

The terminal strip 40 will next be described with reference to FIGS. 2 and 3. The terminal strip 40 includes a grounding (GND) conductor 41 as an exemplary first conductor, power supply (VDD) conductors 42 as exemplary second conductors, signal line conductors 43 as exemplary second conductors, and insulators 45 as exemplary insulators electrically insulating the first conductor from the second conductors. The insulators 45 intervene between the GND conductor 41 and the VDD conductors 42 to electrically insulate the GND conductor 41 from the VDD conductors 42. Similarly, the insulators 45 intervene between the GND conductor 41 and the signal line conductors 43 to electrically insulate the GND conductor 41 from the signal line conductors 43. The GND conductor 41 is composed of, for example, Cu. The VDD conductors 42 and the signal line conductors 43 are composed of, for example, Cu. The insulators 45 are composed of, for example, epoxy resin.

Moreover, the terminal strip 40 includes, at each of a top surface 40Aa (40Ba) and a bottom surface 40Ab (40Bb) thereof, the solder layers 47 (not shown) formed of, for example, solders, the solder layers 47 corresponding to the GND conductor 41, the VDD conductors 42, and the signal line conductors 43. The terminal strip 40 further includes, at a portion of each of the top surface 40Aa (40Ba) and bottom surface 40Ab (40Bb) thereof where the solder layers 47 are not provided, an insulating layer 48 formed of, for example, a solder resist as an exemplary insulating layer. In FIGS. 2 and 3, the solder layers 47 are fused with the solder layers 33 formed at the pads 32 at each of the bottom surface 30Ab of the printed wiring board 31 constituting the semiconductor package 30A and the top surface 30Ba of the printed wiring board 31 constituting the semiconductor package 30B to constitute the connection portions 50. The connection portions 50 are barrel-shaped or cylinder-shaped due to surface tension.

The GND conductor 41 is connected to ground potential (GND) as exemplary first potential. The VDD conductors 42 are connected to power supply potential (VDD) as exemplary second potential. The signal line conductors 43 are used as signal lines. In FIGS. 2 and 3, hatching for distinguishing the GND conductor 41, the VDD conductors 42, the signal line conductors 43, and the insulators 45 from each other is shown as legends. The same applies to the following drawings. In this case, other than the GND conductor 41, the VDD conductors 42 and the signal line conductors 43 are provided. Additionally, conductors connected to, for example, third potential and fourth potential may be provided.

In this case, the top surface 40Aa (40Ba) and bottom surface 40Ab (40Bb) of the terminal strip 40 are mirror images to each other.

A path indicated by an arrow 100 is the portion of the terminal strip 40 of a path in the semiconductor module 10 extending from a VDD terminal to a GND terminal, as viewed from the semiconductor chip 20 mounted on the semiconductor package 30A, as shown in FIG. 2. In this manner, in the terminal strip 40, the GND conductor 41 and the VDD conductors 42 are disposed, the physical distance there between being short. In this arrangement, on the path in the semiconductor module 10 extending from the VDD terminal to the GND terminal, as viewed from the semiconductor chip 20 mounted on the semiconductor package 30A, mutual inductance is increased, and thus loop inductance can be decreased.

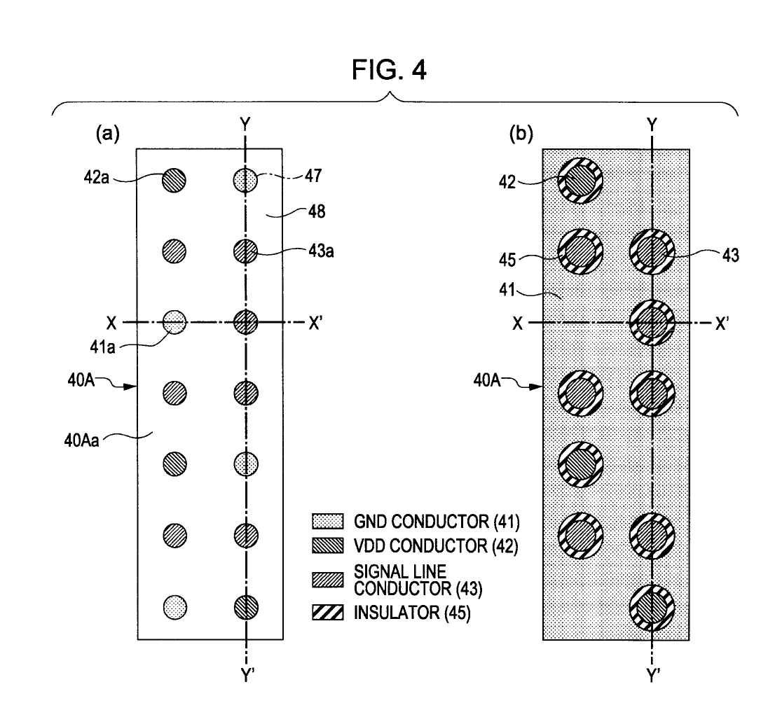

FIG. 4(a) is a plan view of the terminal strip 40A for further describing the terminal strip 40. On the other hand, FIG. 4(b) is a cross sectional view of the terminal strip 40A taken along line Z-Z′ in FIGS. 2 and 3 for further describing the terminal strip 40.

The solder layers 47 and the insulating layer 48 are formed at the top surface 40Aa of the terminal strip 40A, as shown in FIG. 4(a). In this case, when individual groups of the solder layers 47 corresponding to the GND conductor 41, the VDD conductors 42, and the signal line conductors 43 are distinguished from each other, the individual groups of the solder layers 47 are called GND conductor connection portions 41a, VDD conductor connection portions 42a, and signal line conductor connection portions 43a.

The VDD conductors 42 and the signal line conductors 43 are provided at portions of a cross section of the terminal strip 40A corresponding to the VDD conductor connection portions 42a and the signal line conductor connection portions 43a shown in FIG. 4(a), as shown in FIG. 4(b). The insulators 45 surround the respective perimeters of the VDD conductors 42 and the signal line conductors 43. However, no GND conductor 41 surrounded by the insulators 45 exists at portions corresponding to the GND conductor connection portions 41a in FIG. 4(a). That is, as viewed from the cross section, all portions of the terminal strip 40A except the VDD conductors 42, the signal line conductors 43, and the insulators 45 surrounding the VDD conductors 42 and the signal line conductors 43 are the GND conductor 41.

Thus, the GND conductor 41 is disposed close to the VDD conductors 42 and the signal line conductors 43. In the terminal strip 40, when the GND conductor 41 and the VDD conductors 42 are disposed close to each other, on the path in the semiconductor module 10 extending from the VDD terminal to the GND terminal, as viewed from the semiconductor chip 20 mounted on the semiconductor package 30A, mutual inductance is increased, and thus loop inductance can be decreased, as described above.

In the terminal strip 40, the GND conductor 41 having a tabular shape and including a plurality of through holes that extend in the strip thickness direction is provided, and the plurality of VDD conductors 42 and the plurality of signal line conductors 43 are provided inside the through holes so as to extend from the top surface of the GND conductor 41 to reach the bottom surface, as described above. Moreover, the insulators 45 intervene between the GND conductor 41 and the plurality of VDD conductors 42 so as to electrically insulate the GND conductor 41 from the VDD conductors 42, the insulators 45 surrounding the respective perimeters of the VDD conductors 42. Similarly, the insulators 45 intervene between the GND conductor 41 and the plurality of signal line conductors 43 so as to electrically insulate the GND conductor 41 from the signal line conductors 43, the insulators 45 surrounding the respective perimeters of the signal line conductors 43.

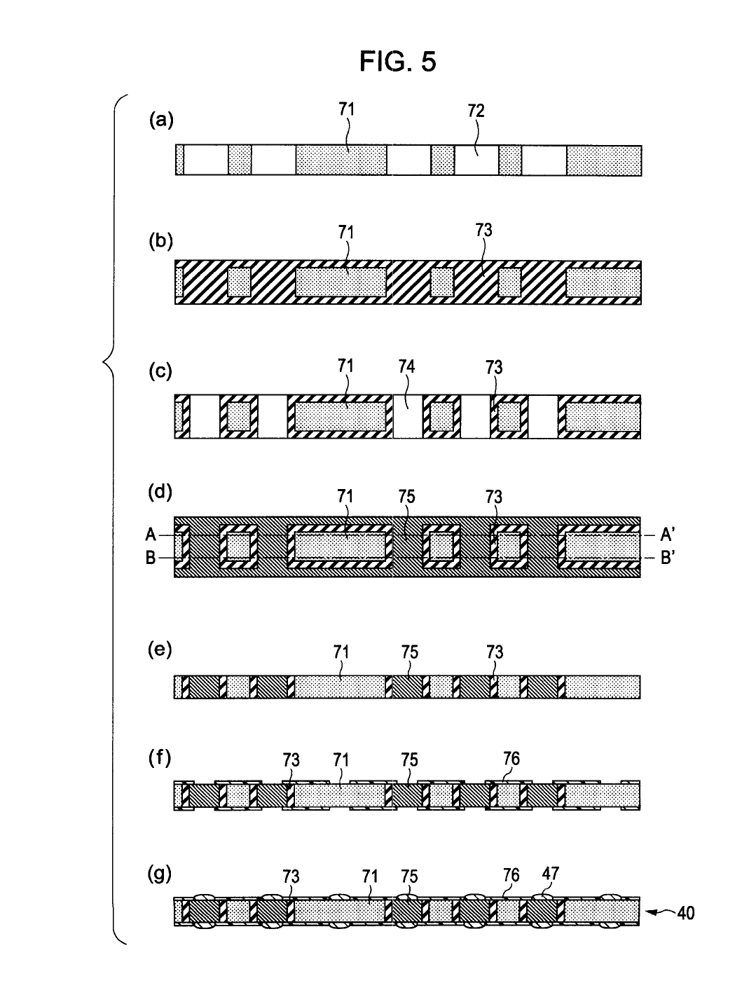

A method for manufacturing the terminal strip 40 in the first embodiment, i.e., steps of manufacturing the terminal strip 40, will next be described. FIG. 5 is a diagram showing the method for manufacturing the terminal strip 40. In this case, the method for manufacturing the terminal strip 40 will be described on the basis of a cross section (refer to FIG. 3) of the terminal strip 40A taken along line Y-Y′ shown in FIG. 1.

In FIG. 5(a), through holes 72 as exemplary first through holes are bored through portions of a conductor plate 71 as the exemplary first conductor, the VDD conductors 42 and the signal line conductors 43 being to be formed in the portions, using, for example, a drill. The conductor plate 71 is, for example, a Cu plate and will constitute the GND conductor 41. The thickness of the conductor plate 71 is, for example, 150 pin. The diameter of the through holes 72 is, for example, 400 μm.

Moreover, the distance between the respective centers of one of the VDD conductors 42 and a corresponding one of the signal line conductors 43 and the distance between the respective centers of adjacent ones of the signal line conductors 43 are, for example, 500 μm. In this case, a drill is used to form the through holes 72. Alternatively, a punching method using a press or a machining method using irradiation with high-energy emitted light beams such as YAG laser beams may be used. The cross section of the through holes 72 need not necessarily be circular and may be, for example, rectangular.

In steps described below, all objects in process in the steps are called the conductor plate 71.

Then, in FIG. 5(b), the through holes 72 of the conductor plate 71 are filled with an insulator 73 of, for example, epoxy resin. For example, after uncured epoxy resin is applied to the conductor plate 71, the epoxy resin may be cured by heat or ultraviolet rays to form the insulator 73 of epoxy resin. In FIG. 5(b), the insulator 73 covers the top and bottom surfaces of the conductor plate 71. However, the insulator 73 need not necessarily cover the top and bottom surfaces of the conductor plate 71 as long as the insulator 73 fills up the through holes 72. The insulator 73 will constitute the insulators 45.

Then, in FIG. 5(c), through holes 74 as exemplary second through holes are bored through portions of the conductor plate 71 where the VDD conductors 42 and the signal line conductors 43 are to be formed, i.e., portions of the through holes 72 filled with the insulator 73, using, for example, a drill. At thus time, the diameter of the through holes 74 is set to be smaller than the diameter of the through holes 72 so that the insulator 73 remains at the respective inner walls of the through holes 72. The diameter of the through holes 74 is, for example, 300 μm. In this case, the insulator 73 with a thickness of 50 μm remains at the respective inner walls of the through holes 72. In this case, a drill is used to form the through holes 74. Alternatively, a punching method using a press or a machining method using irradiation with high-energy emitted light beams such as YAG laser beams may be used, as is the case with the through holes 72. The cross section of the through holes 74 need not necessarily be circular and may be, for example, rectangular.

Then, in FIG. 5(d), the through holes 74 of the conductor plate 71 are filled with a conductor 75 as the exemplary second conductors. The conductor 75 is composed of, for example, Cu. The conductor 75 is formed by forming a thin Cu film on the surfaces of the conductor plate 71 by electroless plating and then plating the top surface of the film with Cu by electrolytic plating. The conductor 75 will constitute the VDD conductors 42 or the signal line conductors 43. Moreover, the conductor 75 may constitute conductors connected to, for example, the third potential and the fourth potential other than the VDD conductors 42 or the signal line conductors 43.

Then, in FIG. 5(e), portions of the conductor plate 71 from the top and bottom surfaces to line A-A′ and line B-B′ in FIG. 5(d) are removed by, for example, mechanical polishing. At this time, portions of the top and bottom surfaces of the conductor plate 71 are also preferably removed so that the conductor plate 71 is completely electrically insulated from the conductor 75. In this case, the conductor plate 71 is polished so that the thickness of the conductor plate 71 is, for example, 115 μm.

Mechanical polishing may be performed, using slurry containing abrasive grains of, for example, alumina. Moreover, the sandblasting technique for polishing by spraying abrasive grains may be used.

In this case, any method can be used as long as the conductor 75 and the insulator 73 formed at the top and bottom surfaces of the conductor plate 71 and the conductor plate 71 can be evenly removed regardless of the material.

In this manner, a structure in which the conductor 75 surrounded by the insulator 73 is embedded in the through holes 72 provided in the conductor plate 71 is formed. The structure of the top surface of the conductor plate 71 in this state is similar to that of a cross section (refer to FIG. 4(b)) taken along line Z-Z′ shown in FIGS. 2 and 3.

Subsequently, in FIG. 5(f), an insulating film 76 is formed at each of the top and bottom surfaces of the conductor plate 71. At this time, the insulating film 76 is formed at portions other than portions where the VDD conductor connection portions 42a and the signal line conductor connection portions 43a are to be formed and portions where the GND conductor connection portions 41a are to be formed. The insulating film 76 may be formed of, for example, an insulative and photosensitive solder resist. Specifically, a solder resist is applied to the top surface of the conductor plate 71, and then portions of the solder resist where the GND conductor connection portions 41a, the VDD conductor connection portions 42a, and the signal line conductor connection portions 43a are to be formed are removed, using what is called the photo lithography technique. The same processing is applied to the bottom surface of the conductor plate 71. The insulating film 76 will constitute the insulating layer 48.

Then, in FIG. 5(g), the solder layers 47 are formed by, for example, soldering at portions of each of the top and bottom surfaces of the conductor plate 71 where the insulating film 76 is not formed. Specifically, solders may be formed at portions of each of the top and bottom surfaces of the conductor plate 71 where the insulating film 76 of a solder resist is not formed by printing solder cream on the conductor plate 71, using the screen printing technique.

In this manner, the terminal strip 40 is completed.

In this case, the conductor 75 embedded in the through holes 72 provided in the conductor plate 71 may be used for both the VDD conductors 42 and the signal line conductors 43. Moreover, the conductor 75 may be used for conductors connected to, for example, the third potential and the fourth potential. The terminal strip 40 has a structure in which the VDD conductors 42 and the signal line conductors 43 surrounded by the insulators 45 are embedded in the through holes provided in the conductor plate 71 having a tabular shape, as described above.

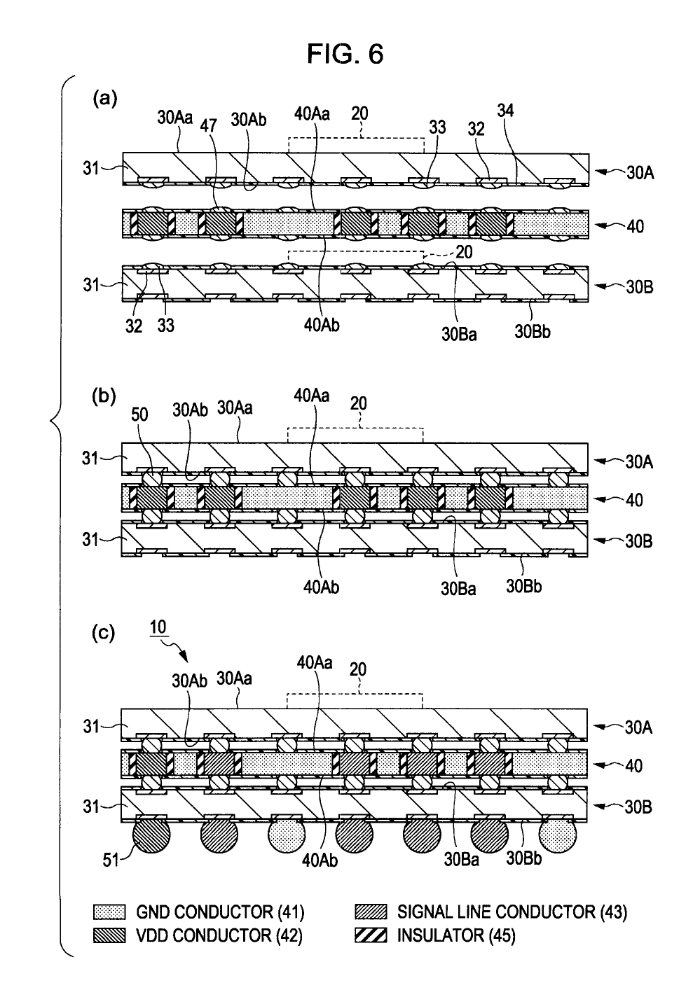

A method for manufacturing the semiconductor module 10, using the completed terminal strip 40, i.e., connection steps of connecting a plurality of semiconductor packages 30, sandwiching the terminal strip 40 between the semiconductor packages 30, will next be described. FIG. 6 is a diagram showing the method for manufacturing the semiconductor module 10. In FIG. 6(a), the respective positions of the solder layers 33 at the bottom surface 30Ab of the semiconductor package 30A including the semiconductor chip 20 are first aligned to and brought in contact with the respective positions of the solder layers 47 at the top surface 40Aa (40Ba) of the terminal strip 40A (40B). Although the terminal strip 40B is not shown in FIG. 6(a), the step is performed on the terminal strip 40B at the same time.

Similarly, the respective positions of the solder layers 47 at the bottom surface 40Ab (40Bb) of the terminal strip 40A (40B) are aligned to and brought in contact with the respective positions of the solder layers 33 at the top surface 30Ba of the semiconductor package 30B including the semiconductor chip 20.

In FIG. 6(b), heat is applied until the melting temperature of solders provided in the solder layers 33 and the solder layers 47 is reached. Then, the solders are fused together, so that the semiconductor package 30A, the terminal strip 40A (40B), and the semiconductor package 30B are connected to each other. At this time, the solders in the solder layers 33 and the solder layers 47 in contact with each other are fused together to constitute the connection portions 50, which are barrel-shaped or cylinder-shaped due to surface tension.

Finally, in FIG. 6(c), the connection terminals 51 of, for example, solder balls are formed at the pads 32 provided at the bottom surface 30Bb of the semiconductor package 30B. The solder balls may be formed by, for example, putting ball-shaped solders on the bottom surface 30Bb of the semiconductor package 30B and then heating the solders.

In this manner, the semiconductor module 10 is completed. Then, the conductor 75 embedded in the through holes 72 provided in the conductor plate 71 is set as the VDD conductors 42 or the signal line conductors 43. Furthermore, the conductor 75 may be set as conductors connected to, for example, the third potential and the fourth potential other than the VDD conductors 42 or the signal line conductors 43.

In the first embodiment, the step of applying heat is used multiple times to melt solders. Since the conductor plate 71 is not melted, the distance between the top and bottom semiconductor packages 30A and 30B can be readily maintained. In this case, the connection terminals 51 of solder balls may be formed by putting ball-shaped solders on the bottom surface 30Bb of the printed wiring board 31 constituting the semiconductor package 30B in FIG. 6(a) and applying heat in FIG. 6(b), together with the connection portions 50. The number of times the step of applying heat is performed can be reduced.

An example and a comparative example in the embodiment will next be described.

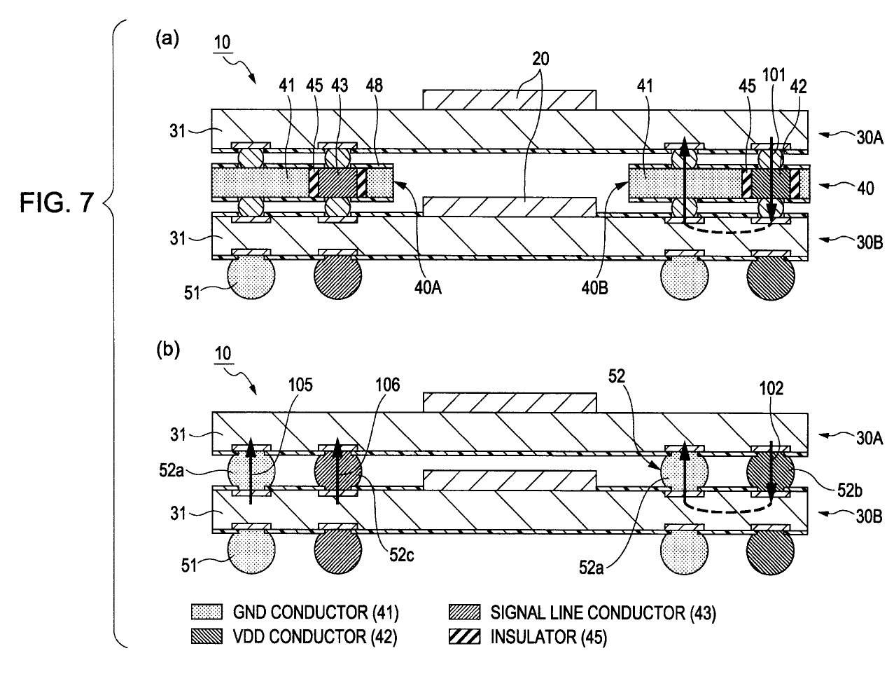

FIG. 7(a) and (b) are diagrams showing respective semiconductor modules 10 of the example and the comparative example.

The example will first be described.

The semiconductor module 10 of the example shown in FIG. 7(a) is that shown in the first embodiment shown in FIG. 1. The diameter of each of the VDD conductors 42 is set to 300 μm, and the diameter of the perimeter of each of the insulators 45 is set to 400 μm. That is, the thickness of the insulator 45 is 50 μm. Moreover, the relative dielectric constant of the insulator 45 is 2.1.

That is, in the terminal strip 40, the GND conductor 41 and the VDD conductors 42 are separated by the insulators 45 with a thickness of 50 μm. Moreover, the distance between the respective centers of the GND conductor 41 and each of the VDD conductors 42 is 500 μm. Moreover, the thickness of the portion of the GND conductor 41 in the terminal strip 40 is 115 μm. The distance between the pads 32 of the semiconductor package 30A and the pads 32 of the semiconductor package 30B opposing each other, sandwiching the terminal strip 40, is 225 μm.

In this case, as shown in a path 101 indicated by an arrow in FIG. 7(a), the loop inductance L of only the portion of the terminal strip 40 of a path in the semiconductor module 10 extending from a VDD terminal to a GND terminal, as viewed from the semiconductor chip 20 mounted on the semiconductor package 30A, is evaluated. That is, the evaluated loop inductance L corresponds to solid-line parts (mainly the GND conductor 41 and VDD conductor 42), except a broken-line part, of the path 101 indicated by the arrow. This is because the purpose is to exclude the influence of internal wiring and the like in the printed wiring boards 31 constituting the semiconductor packages 30A and 30B and clarify only the characteristics of the terminal strip 40.

Moreover, capacitance C between the two solid-line parts (mainly the GND conductor 41 and the VDD conductor 42) extracted from the path 101 indicated by the arrow is evaluated. More specifically, two groups each of which includes a portion of the GND conductor 41 and one of the VDD conductors 42 described above are set, and the two portions of the GND conductor 41 and the two VDD conductors 42 are connected to each other. Then, the loop inductance L and the capacitance C are evaluated.

The comparative example will next be described. The semiconductor module 10 of the comparative example shown in FIG. 7(b) is that in which the semiconductor packages 30A and 30B are connected by solder balls 52. The diameter of the solder balls 52 is 325 μm. The distance between the respective centers of a GND connection portion 52a and a VDD connection portion 52b of the solder balls 52 connecting the semiconductor packages 30A and 30B is 500 μm, as is the case with the example. Thus, the GND connection portion 52a and the VDD connection portion 52b are separated by an air gap with a length of 175 μm.

In this case, as shown in a path 102 indicated by an arrow in FIG. 7(b), the loop inductance L of mainly the GND connection portion 52a and the VDD connection portion 52b of a path in the semiconductor module 10 extending from a VDD terminal to a GND terminal, as viewed from the semiconductor chip 20 mounted on the semiconductor package 30A, is evaluated. That is, the evaluated loop inductance L corresponds to solid-line parts (mainly the GND connection portion 52a and the VDD connection portion 52b), except a broken-line part, of the path 102 indicated by the arrow. This is because the purpose is to exclude the influence of internal wiring and the like in the printed wiring boards 31 constituting the semiconductor packages 30A and 30B and clarify only the characteristics of the GND connection portion 52a and the VDD connection portion 52b, as described above. Moreover, capacitance C between the solid-line parts (the respective parts of the GND connection portion 52a and the VDD connection portion 52b) extracted from the path 102 indicated by the arrow is evaluated.

More specifically, two groups each of which includes the GND connection portion 52a and the VDD connection portion 52b described above are set, and the two GND connection portions 52a and the two VDD connection portions 52b are connected to each other. Then, the loop inductance L and the capacitance C are evaluated.

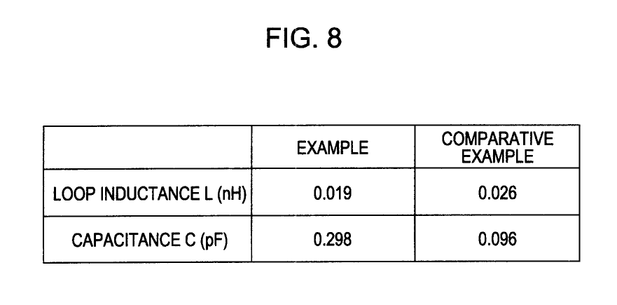

FIG. 8 is a diagram showing the loop inductance L and the capacitance C of each of the respective semiconductor modules 10 of the example and the comparative example described above. The loop inductance L of the semiconductor module 10 of the example is 0.019 nH and decreases by 26% compared with 0.026 nH in the comparative example. This is because, in the terminal strip 40, the GND conductor 41 and the VDD conductor 42 are disposed close to each other with the insulator 45 therebetween, the distance therebetween being 50 μm. On the other hand, the capacitance C of the semiconductor module 10 of the example is 0.298 pF that is about 3.1 times as large as 0.096 pF in the comparative example. This is because, in the terminal strip 40, the GND conductor 41 and the VDD conductor 42 are disposed close to each other with the insulator 45 therebetween, the distance therebetween being 50 μm.

In the semiconductor module 10 according to the first embodiment, an effect of decreasing the loop inductance is achieved, as described above. At the same time, an increase in the capacitance C causes an effect of suppressing variations in power supply voltage. This is preferable from the viewpoint of power integrity.

The semiconductor module 10 according to the first embodiment has a structure in which the terminal strip 40 is sandwiched by the two semiconductor packages 30A and 30B. However, the structure is not limited to a two-layer structure.

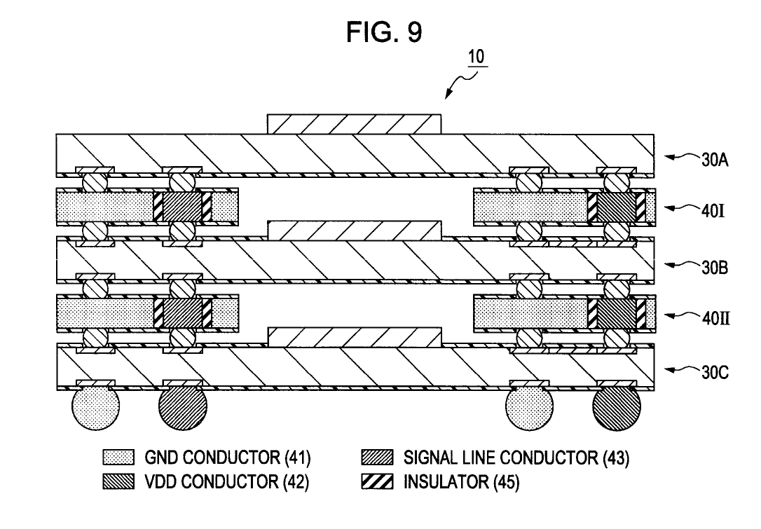

FIG. 9 is a diagram showing the semiconductor module 10, in which the three semiconductor packages 30 are stacked. In this case, terminal strips 401 are provided between the semiconductor packages 30A and 30B, and terminal strips 4011 are provided between the semiconductor package 30B and a semiconductor package 30C.

The semiconductor module 10, in which the three semiconductor packages 30 are stacked, can be manufactured by the manufacturing method shown in FIG. 6 by stacking the terminal strips 401 between the semiconductor packages 30A and 30B and the terminal strips 4011 between the semiconductor packages 30B and 30C in FIG. 6(a). Moreover, the four or more semiconductor packages 30 may be stacked.

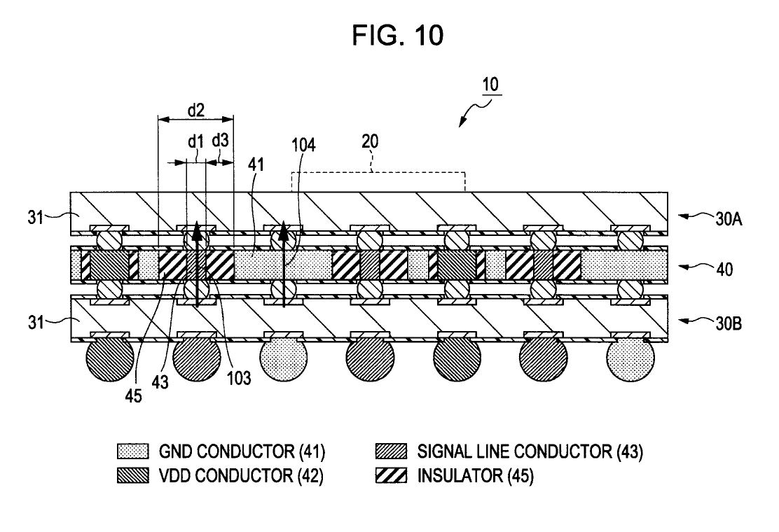

FIG. 10 is a diagram describing the semiconductor module 10 according to a second embodiment. The semiconductor module 10 according to the second embodiment is different from the semiconductor module 10 according to the first embodiment in the diameter of the signal line conductors 43 and the outer diameter of the insulators 45 in the terminal strip 40.

In the example of the semiconductor module 10 according to the first embodiment, in the terminal strip 40, the capacitance C between the GND conductor 41 and the VDD conductor 42 is about 3.1 times as large as that in the comparative example, as described above. This is because, in the terminal strip 40, the GND conductor 41 and the VDD conductor 42 are disposed close to each other.

Thus, in the semiconductor module 10 according to the first embodiment, in the terminal strip 40, the capacitance C between the GND conductor 41 and each of the signal line conductors 43 is also larger than that in the comparative example. This is not preferable because the delay in signal transmission increases.

Accordingly, in the semiconductor module 10 according to the second embodiment, the distance between the GND conductor 41 and the signal line conductor 43 is increased by setting the diameter of the signal line 43 to be smaller than that in the first embodiment and setting the diameter of the perimeter of the insulator 45 surrounding the signal line conductor 43 to be larger than that in the first embodiment.

In the semiconductor module 10 according to the second embodiment shown in FIG. 10, the diameter of the signal line 43 is decreased, and the diameter of the perimeter of the insulator 45 surrounding the signal line conductor 43 is increased. Alternatively, only one of these arrangements may be adopted.

Moreover, the distance between the respective centers of the GND conductor 41 and the VDD conductor 42, the diameter of the VDD conductor 42, and the outer diameter of the insulator 45 in the terminal strip 40 according to the second embodiment may be the same as those in the first embodiment.

An example and a comparative example in the second embodiment will next be described.

It is assumed that the diameter of the signal line conductor 43 is d1. Moreover, it is assumed that the outer diameter of the insulator 45 surrounding the signal line conductor 43 is d2. Then, (d2−d1)/2 is a thickness d3 (the distance between the GND conductor 41 and the signal line conductor 43) of the insulator 45 surrounding the signal line conductor 43.

In the example, the distance between the respective centers of the GND conductor 41 and the signal line conductor 43 is set to 500 μm, and d1 and d2 are changed. The other arrangements in the example are the same as those in the example of the first embodiment.

In this case, as shown in FIG. 10, capacitance C1 between a path 103 (mainly the signal line conductor 43) indicated by an arrow and a path 104 (mainly the GND conductor 41) indicated by another arrow is evaluated. This is because the purpose is to exclude the influence of internal wiring and the like in the printed wiring boards 31 constituting the semiconductor packages 30A and 30B and clarify only the characteristics of the terminal strip 40. The capacitance C1 is evaluated in a group of the GND conductor 41 and the signal line conductor 43.

The comparative example is the semiconductor module 10 shown in FIG. 7(b). The semiconductor packages 30A and 30B are connected by the solder balls 52. The capacitance C1 between the GND connection portion 52a and a signal line connection portion 52c (between a path 105 indicated by an arrow and a path 106 indicated by another arrow) shown in FIG. 7(b) is evaluated.

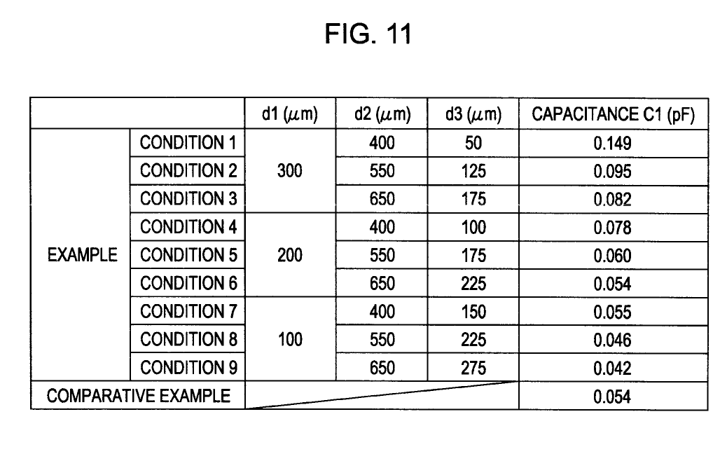

FIG. 11 is a diagram showing the capacitance C1 in a case where the respective values of the diameter d1 of the signal line conductor 43 and the outer diameter d2 of the insulator 45 surrounding the signal line conductor 43 are changed in the semiconductor module 10 according to the second embodiment. The thickness d3 of the insulator 45 varies with d1 and d2.

In each of the respective groups of conditions 1 to 3, conditions 4 to 6, and conditions 7 to 9 in the example, the diameter d1 of the signal line conductor 43 is the same, and the thickness d3 of the insulator 45 is changed.

The conditions 1 to 3 correspond to a case where the diameter d1 of the signal line conductor 43 is 300 μm. Under the condition 1 under which the thickness d3 of the insulator 45 is 50 μm, the capacitance C1 is 0.149 pF. Under the condition 3 under which the thickness d3 of the insulator 45 is 175 μm that is 3.5 times as large as that under the condition 1, the capacitance C1 decreases to 0.082 pF. That is, as the thickness d3 of the insulator 45 is increased, the capacitance C1 decreases.

The conditions 4 to 6 correspond to a case where the diameter d1 of the signal line conductor 43 is 200 μm. Under the condition 5 under which the thickness d3 of the insulator 45 is 175 μm, the capacitance C1 is 0.060 pF. This value is smaller than 0.082 pF under the condition 3 under which the thickness d3 of the insulator 45 is 175 μm, as is the case with the condition 5. The diameter d1 of the signal line conductor 43 is 300 μm under the condition 3. Thus, as the diameter d1 of the signal line conductor 43 is decreased, the capacitance C1 decreases.

The conditions 7 to 9 correspond to a case where the diameter d1 of the signal line conductor 43 is 100 μm. Under the condition 7 under which the thickness d3 of the insulator 45 is 150 μm, the capacitance C1 is 0.055 pF. Under the condition 9 under which the thickness d3 of the insulator 45 is 275 μm, the capacitance C1 is 0.042 pF.

In this case, in the semiconductor module 10 of the comparative example, the capacitance C1 between the GND connection portion 52a and the signal line connection portion 52c (between the path 105 indicated by the arrow and the path 106 indicated by the other arrow) shown in FIG. 7(b) is 0.054 pF. Thus, under the conditions 7 to 9, the capacitance C1 can be substantially equal to or less than that in the comparative example.

In the second embodiment, an effect of decreasing the capacitance C1 between the GND conductor 41 and the signal line conductor 43 in the terminal strip 40 can be achieved by setting the diameter d1 of the signal line conductor 43 to be smaller than that in the first embodiment and setting the thickness d3 of the insulator 45 surrounding the signal line conductor 43 to be larger than that in the first embodiment in the terminal strip 40, as described above. In this case, when the cross section of the signal line conductor 43 has a shape other than a circle, for example, a rectangle, instead of decreasing the diameter d1, the area of the cross section is reduced.

Moreover, in the second embodiment, the distance between the GND conductor 41 and the VDD conductor 42 in the terminal strip 40 is the same as that in the first embodiment, as described above. Thus, even in the second embodiment, an effect of decreasing the loop inductance L through the GND conductor 41 and the VDD conductor 42 in the terminal strip 40 can be achieved.

That is, the distance between the GND conductor 41 and the VDD conductor 42 (the second conductor) and the distance between the GND conductor 41 and the signal line conductor 43 (the second conductor) may be set in a manner that depends on the application of the second conductor, i.e., whether the second conductor is the VDD conductor 42 or the signal line conductor 43. In this case, the application of the second conductor may be, for example, the third potential or the fourth potential other than the VDD conductor 42 or the signal line conductor 43, and the distance between the GND conductor 41 and the second conductor may be set in a manner that depends on the application.

In the terminal strip 40 in the semiconductor module 10 according to the second embodiment, the thickness of the insulator 45 can be changed by using, in the step of forming the through holes 72 in portions where the VDD conductor 42 and the signal line conductor 43 are to be formed shown in FIG. 5(a), different diameters of the through holes 72 for the portion where the VDD conductor 42 is to be formed and the portion where the signal line conductor 43 is to be formed. Moreover, the diameter of the signal line conductor 43 can be changed by using, in the step of forming the through holes 74 in portions where the VDD conductor 42 and the signal line conductor 43 are to be formed in FIG. 5(c), different diameters of the through holes 74 for the portion where the VDD conductor 42 is to be formed and the portion where the signal line conductor 43 is to be formed.

Moreover, in the terminal strip 40, the capacitance C1 between the GND conductor 41 and the signal line conductor 43 may be decreased by setting the dielectric constant of the insulator 45 surrounding the signal line conductor 43 to be smaller than the dielectric constant of the insulator 45 surrounding the VDD conductor 42. In this case, the application of the second conductor may be, for example, the third potential or the fourth potential other than the VDD conductor 42 or the signal line conductor 43, and the dielectric constant of the insulator 45 between the GND conductor 41 and the second conductor may be set in a manner that depends on the application.

The structure of the terminal strip 40 may be implemented in, for example, a manner described below. That is, in the step of forming the through holes 72 in portions where the VDD conductor 42 and the signal line conductor 43 are to be formed shown in FIG. 5(a), for example, the through hole 72 is not formed in the portion where the signal line conductor 43 is to be formed, and the through hole 72 is formed in only the portion where the VDD conductor 42 is to be formed. Then, in FIG. 5(b), the through hole 72 is filled with the insulator 73. Then, returning to FIG. 5(a), the through hole 72 is newly formed in only the portion where the signal line conductor 43 is to be formed. Then, as shown in FIG. 5(b), the newly formed through hole 72 is filled with an insulator having a dielectric constant different from that of the insulator 73. Subsequently, the steps from FIG. 5(c) are performed. In this case, the sequence of the steps of forming the through holes 72 in the portion where the VDD conductor 42 is to be formed and the portion where the signal line conductors 43 is to be formed may be reversed.

That is, the dielectric constant of the insulator 45 between the GND conductor 41 and the VDD conductor 42 (the second conductor) and the dielectric constant of the insulator 45 between the GND conductor 41 and the signal line conductor 43 (the second conductor) may be set in a manner that depends on the application of the second conductor, i.e., whether the second conductor is the VDD conductor 42 or the signal line conductor 43. In this case, the same applies to a case where the application of the second conductor is, for example, the third potential or the fourth potential.

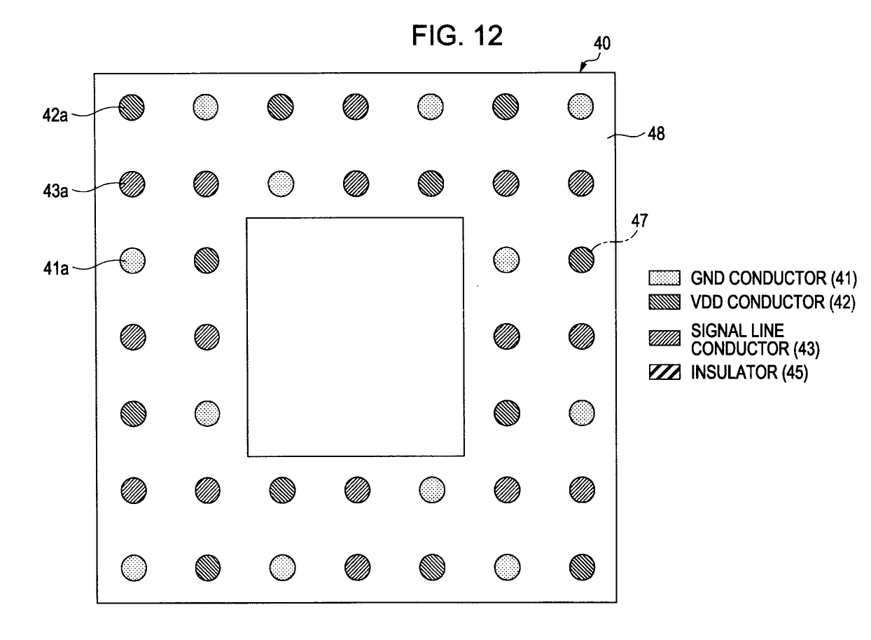

FIG. 12 is a plan view of the terminal strip 40 for describing the terminal strip 40 in the semiconductor module 10 according to a third embodiment. In the first embodiment, the terminal strip 40 is divided into the terminal strips 40A and 40B. In the third embodiment, the terminal strip 40 has a hollow square shape (recessed in square shape). Moreover, the solder layers 47 are formed in a hollow square shape so that the solder layers 47 can surround the semiconductor chip 20 (not shown).

The other arrangements of the semiconductor module 10 and the terminal strip 40 according to the third embodiment are the same as those in the first embodiment. Thus, in the semiconductor module 10 according to the third embodiment, an affect of increasing the number of connectable terminals compared with the first embodiment can be achieved.

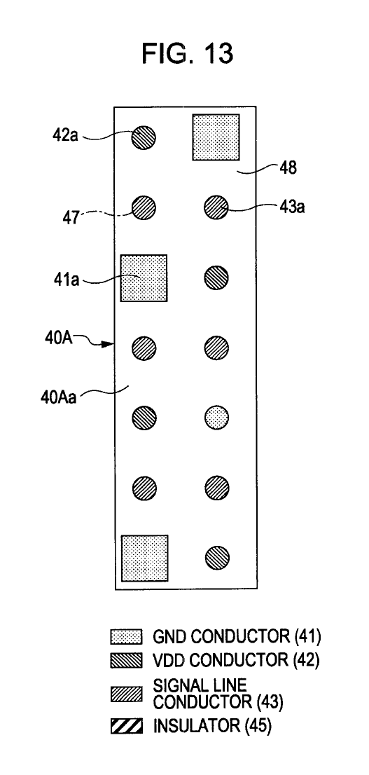

FIG. 13 is a plan view of the terminal strip 40 for describing the terminal strip 40 in the semiconductor module 10 according to a fourth embodiment. In the semiconductor module 10 according to the first embodiment, the GND conductor connection portions 41a of the terminal strip 40A are formed in a circle having the same area as the VDD conductor connection portions 42a or the signal line conductor connection portions 43a, as shown in FIG. 4(a). In contrast, in the terminal strip 40 according to the fourth embodiment, the GND conductor connection portions 41a are formed in a rectangle.

The GND conductor 41 occupies a large portion of the terminal strip 40 excluding portions occupied by the VDD conductors 42, the signal line conductors 43, and the insulators 45 surrounding the VDD conductors 42 and the signal line conductors 43, as shown in FIG. 4(b). Thus, the GND conductor connection portions 41a may be formed, with the area being enlarged, to the extent that the GND conductor connection portions 41a are not electrically shorted to the VDD conductors 42 and the signal line conductors 43.

Thus, in the semiconductor module 10, an affect of decreasing the resistance of a path to a GND terminal of the semiconductor chip 20 can be achieved. In this case, the shape of the GND conductor connection portions 41a is not limited to a rectangle and may be, for example, an ellipse.

In the semiconductor module 10 of the comparative example, the size of the solder balls 52 needs to be decreased to decrease the distance between the solder balls 52, as shown in FIG. 7(b). Then, the distance between the semiconductor packages 30A and 30B is shortened. However, in the semiconductor module 10 according to the embodiment having been described, since the terminal strip 40 is used between the semiconductor packages 30A and 30B, the distance between the semiconductor packages 30A and 30B is not shortened.

Moreover, the thickness of the terminal strip 40 can be increased as needed, as described above. Thus, components such as a thick semiconductor chip and a capacitor can be mounted on the semiconductor package 30B disposed on the bottom side of the semiconductor module 10 by adjusting the thickness of the terminal strip 40. Moreover, the GND conductor 41 occupying a large portion of the terminal strip 40 is composed of, for example, Cu that has a high thermal conductivity, the heat release characteristics are improved compared with air or insulating resin.

In this case, the semiconductor package 30 may not include the semiconductor chip 20 and may include only passive components, for example, capacitors.

Moreover, the description and values in the specification are just examples. Thus, the aforementioned embodiments and values are not restrictive and can be implemented after being appropriately changed.

1. A semiconductor module comprising:
a plurality of semiconductor packages each of which includes a semiconductor chip; and
terminal strips that intervene between the plurality of semiconductor packages and connect the semiconductor packages to each other,
wherein each of the terminal strips includes:
a first conductor that has a tabular shape and includes a plurality of through holes that extend in a strip thickness direction,
a plurality of second conductors provided inside the plurality of through holes so that the second conductors extend from a top surface of the first conductor to reach a bottom surface of the first conductor, and
insulators provided so that the insulators surround respective perimeters of the second conductors, the insulators intervening between the first conductor and the second conductors so as to electrically insulate the first conductor from the second conductors.

2. The semiconductor module according to claim 1, wherein the first conductor is connected to first potential, and some of the plurality of second conductors are connected to second potential different from the first potential, and all or some of the other second conductors are used as signal lines.

3. The semiconductor module according to claim 2, wherein the first potential is ground potential.

4. The semiconductor module according to claim 2, wherein the second conductors used as the signal lines have a smaller cross section than the second conductors connected to the second potential.

5. The semiconductor module according to claim 2, wherein ones of the insulators provided so as to surround respective perimeters of the second conductors used as the signal lines have a larger thickness than ones of the insulators provided so as to surround respective perimeters of the second conductors connected to the second potential, the insulators intervening between the first conductor and the second conductors.

6. The semiconductor module according to claim 2, wherein ones of the insulators provided so as to surround respective perimeters of the second conductors used as the signal lines have a smaller dielectric constant than ones of the insulators provided so as to surround respective perimeters of the second conductors connected to the second potential.

7. A terminal strip that connects a plurality of semiconductor packages to each other, the terminal strip comprising:
a first conductor that has a tabular shape and includes a plurality of through holes that extend in a strip thickness direction;
a plurality of second conductors provided inside the plurality of through holes so that the second conductors extend from a top surface of the first conductor to reach a bottom surface of the first conductor; and
insulators provided so that the insulators surround respective perimeters of the second conductors, the insulators intervening between the first conductor and the second conductors so as to electrically insulate the first conductor from the second conductors.

8. The terminal strip according to claim 7, further comprising:
an insulating layer at each of the top surface and bottom surface of the first conductor.

9. A method for manufacturing a terminal strip that connects a plurality of semiconductor packages to each other, the method comprising the steps of:
forming a plurality of first through holes in a first conductor that has a tabular shape;
filling the plurality of first through holes with an insulator;
forming second through holes in the insulator in the first through holes; and
filling the second through holes with a second conductor.

10. A method for manufacturing a semiconductor module comprising the steps of:
manufacturing a terminal strip that connects a plurality of semiconductor packages to each other; and
connecting the semiconductor packages via the terminal strip sandwiched by the semiconductor packages,
wherein the steps of manufacturing the terminal strip include:
forming a plurality of first through holes in a first conductor that has a tabular shape,
filling the plurality of first through holes with an insulator,
forming second through holes in the insulator in the first through holes, and
filling the second through holes with a second conductor.
